(19) United States
(12) Patent Application Publication
(10) Pub. No.: US 2025/0208514 A1
(43) Pub. Date: Jun. 26, 2025

(54) METHOD FOR IMAGING A MASK LAYER WITH TWO IMAGING SETTINGS AND ASSOCIATED IMAGING SYSTEM

(71) Applicant: XSYS PREPRESS NV, IEPER (BE)

(72) Inventor: Dirk Ludo Julien DE RAUW, NINOVE (BE)

(73) Assignee: XSYS PREPRESS NV, IEPER (BE)

(21) Appl. No.: 18/839,194

(22) PCT Filed: Mar. 1, 2023
(86) PCT No.: PCT/EP2023/055101

§ 371 Date: Aug. 16, 2024

(30) Foreign Application Priority Data
Mar. 2, 2022 (NL) 2031133

(51) Int. Cl. G03F 7/20; G03F 7/00; H04N 1/405

(52) U.S. Cl. CPC G03F 7/2016; G03F 7/704; H04N 1/4057; G03F 7/2055

(57) ABSTRACT

A method for imaging a mask layer includes providing a mask layer, receiving an image file and detecting at least one solid area and at least one halftone area in the image file, imaging an area of the mask layer corresponding to the at least one solid area, using a first imaging setting, wherein prior to or during the imaging a sampling pattern is superimposed on pixels of the at least one solid area, so that only a portion of the pixels of the at least one solid area is imaged, and imaging an area of the mask layer corresponding to said at least one halftone area, using a second imaging setting which is different from the first imaging setting.

### FIELD OF THE INVENTION

The field of the invention relates to imaging a mask layer in the field of printing technology. Various embodiments in this document relate to methods for imaging a mask layer, control modules, and computer programs for use in imaging a mask layer, and to methods and systems for imaging and exposing a relief precursor.

### DESCRIPTION OF RELATED ART

In known methods for imaging a mask layer a fine high-resolution pattern may be included in the image file in a half-tone area and/or in a solid area in order to generate a texture on a surface of a printing dot. Such pattern is typically superimposed on the original image file and may consist of a regular pattern or an irregular pattern, e.g. a checkerboard pattern or a pattern where an imaging pixel is surrounded by eight non-imaging pixels, etc. Such pattern results in a relief structure, i.e. a texture on the printing dots and is intended to improve the ink transfer and thus the printing quality.

Such known methods are however not entirely satisfactory. One problem may be the ink density. A developed spot corresponding to the solid and/or the halftone area may not be able to hold enough ink, such that the ink density of the printed material may appear insufficient, i.e. not dark enough. Another problem may be what is called ‘a trailing edge void’. The trailing edge void appears when the edge of a developed solid spot is badly inked. A third problem that may arise is when a sampling pattern is applied on the solid area and/or the halftone area. The sampling pattern can interfere with the existing pattern of halftone dots in the halftone area.

### SUMMARY OF THE INVENTION

Some embodiments of the present disclosure relate to a mask layer imaging method which may improve the ink density of the printed material. Some embodiments of the present disclosure relate to a mask layer imaging method which may reduce or eliminate the issue of trailing edge voids. Some embodiments may reduce the interference caused by a sampling pattern.

According to a first aspect of the disclosure, a method for imaging a mask layer, comprises the steps of the provision of a mask layer, receiving an image file and detecting at least one solid area and at least one halftone area in the image file, imaging an area of the mask layer corresponding to said at least one solid area using a first imaging setting, and imaging an area of the mask layer corresponding to said at least one halftone area using a second imaging setting. Prior to or during the imaging a sampling pattern is superimposed on pixels of the at least one solid area, so that either all or only a portion of the pixels of the at least one solid area is imaged. The second imaging setting is different from the first imaging setting.

By using a suitable sampling pattern in the solid area an appropriate surface structure can be obtained on the corresponding solid printing relief(s) of a printing plate, and ink on a solid printing relief will be more evenly distributed. As such the trailing edge voids can be much reduced. Indeed, by using a sampling pattern, channels are created in the upper surface of a solid relief such that a resulting printing relief is not in contact with the substrate over a too large area while printing. This reduces the trailing edge void.

In addition, by using different imaging settings when imaging the mask layer corresponding to the solid area and the halftone area, any potential interference under one imaging setting may be prevented from causing interference under another imaging setting. In some embodiments no sampling pattern is applied in the halftone areas, and thus no interference is present in those areas. However, even if a sampling pattern is used in a halftone area and were to cause some interference to the halftone area, interference can be much reduced as the imaging settings of the halftone area can be chosen independently of the imaging settings of the solid area.

Preferably, the resolution of the sampling pattern is chosen in a range from 1000 dpi to 2540 dpi. Preferably, when an ink roll is used to bring the ink on the plate, the resolution is chosen such that it is higher than a resolution of a surface structure of the ink roll.

The first aspect of the disclosure may comprise any one of, or any technically possible combinations of the following features:
said sampling pattern and said first and second imaging settings are chosen such that, after exposing a relief precursor through the imaged mask layer and developing an exposed relief precursor, a first surface structure of hills surrounded by valleys is generated on a printing relief corresponding with said at least one solid area and a second surface structure of hills surrounded by valleys on halftone dots corresponding with said at least one halftone area.

Compared to an ink cell which comprises an ink well containing ink surrounded by a wall preventing ink from escaping from the ink well, the surface structure of hills surrounded by valleys allows ink to distribute evenly across many hills.
the first and second imaging settings are such that an imaged spot corresponding to an imaging pixel of the at least one solid area is larger than an imaged spot corresponding to an imaging pixel of the at least one halftone area. Preferably, a top surface of an imaged spot corresponding to an imaging pixel of the at least one solid area is at least 10%, more preferably at least 20%, even more preferably at least 30% larger, most preferably at least 40% larger than a top surface of an imaged spot corresponding to an imaging pixel of the at least one halftone area.

By using larger imaged spots for the solid area where a sampling pattern is used, the imaged spots may be located closer to each other or overlap, resulting in more “hill” surface area, and the printing result from the solid area can have a darker colour. By using smaller imaged spots in a halftone area, also when no sampling pattern is used, a hill structure can be obtained and a good ink transfer can be obtained.
the sampling pattern is a repetition of a block in which one or more imaging pixels are combined with one or more non-imaging pixels.

Alternating imaging pixels with non-imaging pixels across the whole block leads to a regular sampling i.e. a regular selection of the imaging pixels over the whole block.
the sampling pattern is any one of the following or a combination thereof: a single pixel pattern, such as a single pixel checkerboard pattern, a pattern for which each imaging pixel is surrounded by eight non-imaging pixels; a multiple pixel pattern, such as a multiple pixel checkerboard pattern where e.g. a cluster of four imaging pixels or four non-imaging pixels corresponds with a case of the checkerboard; a line pattern; a dash pattern (such as interrupted lines); a circle pattern.
no sampling pattern is added in the at least one halftone area.

By not applying any sampling pattern in the halftone area, any potential interference between the sampling pattern and the second imaging setting can be totally avoided.
a sampling pattern is added in the at least one halftone area.

By applying a sampling pattern also to the halftone area, a selection can be made as to which of the imaging pixels actually are to be imaged according to the second imaging setting. For example, depending on the tonal values used in the image to be printed, it may be beneficial to use also a sampling pattern in one or more halftone areas. It is further possible to make a distinction between different halftone areas and to apply different sampling patterns (including the option of not including a sampling pattern) in different halftone areas, e.g. depending on a value representative for a tonal value or tonal value range. Also, the second imaging setting may be different for different halftone areas. Optionally, the second imaging setting may be chosen in function of a value representative for a tonal value or for a tonal value range.
for tonal values below a predetermined value, no sampling pattern is added in the at least one halftone area, and for tonal values above the predetermined value, a sampling pattern is added in the at least one halftone area. In a similar embodiment, isolated pixel clusters containing a number of pixels lower than a predetermined value of pixels are detected, and no sampling pattern is added for such small isolated pixel clusters, whilst for the other areas, a sampling pattern is added. In that manner, not only halftone areas with a low tonal value but any very small image areas will not receive a sampling pattern.

Here, whether a sampling pattern is added to the halftone area depends on the tonal value in the halftone area. For low tonal values all imaging pixels in the halftone area are to be imaged on the mask layer. All information related to the low tonal values will therefore be represented in the mask layer. For high tonal values a selection as to which imaging pixels are to be imaged on the mask layer is carried out via the sampling pattern. In this way a good balance between the depth of the colour and the application of the sampling pattern may be achieved.
the at least one halftone area comprises a first and second halftone area, wherein the first halftone area is imaged using the second imaging setting, and wherein the second halftone area is imaged using a third imaging setting, the method comprising the step of imaging an area of the mask layer corresponding to said at least one halftone area, using the third imaging setting which is different from the first imaging setting.

By using at least two different imaging settings for the halftone areas, the image setting may be adapted, e.g. based on the tonal value of the halftone area and/or on other properties of the halftone area. By providing at least two imaging settings for the halftone area, various results inside the halftone areas can be obtained.
the image file represents two-dimensional image data, wherein preferably the image file is a 1 bit per pixel file or a multi-level image file with multiple bits per pixel.

The 1-bit-per-pixel possibility simplifies the image file and the imaging process, while the multiple-bits-per-pixel embodiment increases the number of imaging options contained in a single image file.
the first and second imaging setting each specifies a value which is representative for a size and/or shape (e.g. a diameter if the imaged spot is round) of an imaged spot corresponding with an imaging pixel;
the first and second imaging settings define any one or more of the following parameters:
   an intensity value to be used for generating an imaged feature corresponding with an imaging pixel, e.g. an intensity value for controlling a beam used for the imaging of the at least one solid area and the at least one half-tone area, respectively,
   a time interval to be used for generating an imaged feature corresponding with an imaging pixel, e.g. an on-time value for controlling a beam used for the imaging of the at least one solid area and the at least one halftone area, respectively,
   a beam diameter value or beam shape value for controlling a beam used for the imaging of the at least one solid area and the at least one halftone area, respectively,
   a number of passes used for the imaging of the at least one solid area and the at least one halftone area, respectively,
   an indication of an exposure head of a plurality of exposure heads to be used for generating an imaged feature or a group of imaged features corresponding to a pixel or a group of pixels for the imaging of the at least one solid area and the at least one halftone area, respectively.
Preferably, the first imaging setting is a first intensity and the second imaging setting is a second intensity, and the first intensity is at least 1.5 times higher, more preferably at least 2 times higher, than the second intensity.
a solid area of the at least one solid area corresponds to a single relief area i.e. an area where a single imaging pixel cluster and no repetition of similarly sized imaging pixel clusters is present, typically an area having a tonal value of 100%. A halftone area of the at least one halftone area corresponds to an area where multiple similarly sized imaging pixel clusters are present at a distance of each other, i.e. an area having a tonal value of less than 100%. Embodiments of the invention are 10 especially useful for classic amplitude modulated (AM) screens, i.e. image files containing halftone areas where the distance between a first group of clustered imaging pixels corresponding with a first dot and a second group of clustered imaging pixels corresponding with an adjacent second dot of a halftone area is the same for all halftone areas, i.e. for halftone areas having different tonal values. Stated differently, the number of dots per cm² is the same for all halftone areas. The tonal value of the halftone area is then determined by the size of a group of clustered imaging pixels (i.e. the size of a dot). However, the skilled person understands that other embodiments of the invention may be used for frequency modulated (FM) screens or AM and FM screens, where the distance is not constant and where also the number of dots per cm² is changed.
the step of detecting at least one solid area and at least one halftone area in the image file is done during a raster image processing step. In an exemplary embodiment at least one first raster image file is generated containing only one or more solid areas of the at least one solid area and at least one second raster image file containing only one or more halftone areas of the at least one halftone area. In such an embodiment, the images files may be for example a first one-bit-per-pixel file for the at least one solid area when the same first imaging setting is used for all solid areas and a second one-bit-per-pixel file for the at least one halftone area when the same second imaging setting is used for all halftone areas. If more than two imaging settings are used, more than two raster image files may be generated, e.g. a first one for the at least one solid area, a second one for one or more first halftone areas with a tonal value within a first tonal value range and a third one for one or more second halftone areas with a tonal value within a second tonal value range. Alternatively, a multi-bit per pixel file may be generated, see further.

In this way, the information about the solid area(s)/halftone area(s) can be derived from the original image file, e.g. a pdf file, which contains typically information about grey values, also called contones, an indication of areas with characters or line work and an indication of areas with contones, etc., which may facilitate the detection and make it more accurate. For example, line work will typically correspond with a solid area whilst contones result in halftone areas, optionally with a solid area within the contones.
the image file is a raster image file and the step of detecting at least one solid area and at least one halftone area in the image file is performed after a raster image processing step.

By doing the detection on the raster image file, e.g. a tiff file, the method becomes independent of any prior image processing steps, such as a raster image processing step or other image processing step done beforehand, which allows the method to be used in any imager regardless of prior image processing steps. In such an embodiment, the method may detect groups of clustered pixels to determine the solid and halftone areas.
prior to the imaging, a modified image file is generated, said modified image file having at least two bits per pixel, said at least two bits indicating for each pixel whether the pixel is one of the following:
   a non-imaging pixel,
   an imaging pixel to be imaged with the first imaging setting,
   an imaging pixel to be imaged with the second imaging setting,
   optionally an imaging pixel to be imaged with a third imaging setting,
wherein the imaging is done based on the modified image file.

These features integrate an indication of the imaging setting to be used into a single modified image file. During the imaging of the mask layer, it is then only necessary to extract information from this modified image file without having to refer to other files and/or without the need for having multiple raster image files.

A further aspect of the disclosure concerns a method for imaging and exposing a relief precursor, comprising the steps of the provision of a relief precursor comprising a substrate layer, a photosensitive layer, and a mask layer; imaging the mask layer by a method according to any one of the embodiments disclosed above; exposing the relief precursor through the imaged mask layer with electromagnetic radiation, preferably UV radiation, so that a portion of the photosensitive layer is cured, and developing the exposed relief precursor by removing a portion of the photosensitive layer that was not exposed.

According to one embodiment of the method for imaging and exposing the relief precursor, a solid area of said at least one solid area is such that, after the exposing and developing, a single printing relief with a first surface structure of hills surrounded by valleys is generated in said solid area, and a halftone area of said at least one halftone area is such that, after developing, multiple dots with a second surface structure of hills surrounded by valleys is generated in said halftone area.

In this way an appropriate texture is given to both the one or more solid printing reliefs corresponding with the one or more solid areas and to the halftone dots corresponding with the at least one halftone area, resulting in a good ink transfer.

Another aspect of the present disclosure also relates to an imaging system, the imaging system being configured to perform the method as described above.

Another aspect of the present disclosure relates to a control module configured to receive an image file and to detect at least one solid area and at least one halftone area in an image file. The control module is configured to control an imager so that an area of the mask layer corresponding to said at least one solid area is imaged using a first imaging setting. Prior to or during the imaging the control module is configured to superimpose a sampling pattern on pixels of the at least one solid area, so that only a portion of the pixels of the at least one solid area is imaged, and so that an area of the mask layer corresponding to said at least one halftone area is imaged using a second imaging setting.

The control module of the disclosure may comprise any one of, or any technically possible combinations of the following features:
the control module is configured to select or set the sampling pattern and said first and second imaging settings such that, after exposing a relief precursor through the imaged mask layer and developing an exposed relief precursor, a first surface structure of hills surrounded by valleys is generated on a relief corresponding with said at least one solid area and a second surface structure of hills surrounded by valleys on printing dots corresponding with said at least one halftone area.
the control module is configured to select or set the first and second imaging settings such that an imaged spot corresponding to an imaging pixel of the at least one solid area is larger than an imaged spot corresponding to an imaging pixel of the at least one halftone area.
the control module is configured to select or set the sampling pattern as a repetition of a block in which one or more imaging pixels are combined with one or more non-imaging pixels.
the sampling pattern is any one of the following or a combination thereof: a single pixel pattern, such as a single pixel checkerboard pattern, a pattern for which each imaging pixel is surrounded by eight non-imaging pixels; a multiple pixel pattern, such as a multiple pixel checkerboard pattern; a line pattern; a dash pattern; a circle pattern.
the control module is configured so that no sampling pattern is added in the at least one halftone area.
the control module is configured so that a sampling pattern is added in the at least one halftone area.
the control module is configured to determine whether or not to apply a sampling pattern in a halftone area of said at least one halftone area depending on the tonal value of that halftone area.
the control module is configured so that for tonal values below a predetermined value, no sampling pattern is added in the at least one halftone area, and for tonal values above the predetermined value, a sampling pattern is added in the at least one halftone area.
the control module is configured so that, when the at least one halftone area comprises a first and second halftone area, the first halftone area is imaged using the second imaging setting, and the second halftone area is imaged using a third imaging setting, wherein the third imaging setting is different from the first imaging setting.
the control module is configured to generate an image file representing two-dimensional image data, wherein preferably the image file is a 1 bit per pixel file or a multi-level image file with multiple bits per pixel.
the control module is configured so that the first and second imaging settings each specifies a value which is representative for a size and/or shape (e.g. a diameter if the imaged spot is round) of an imaged spot corresponding with an imaging pixel; and preferably such that the first and second imaging settings define any one or more of the parameters specified above in connection with embodiments of the method.
the control module is configured to do raster image processing of the image file and to perform the step of detecting at least one solid area and at least one halftone area during the raster image processing step, wherein optionally at least one first raster image file is generated containing only one or more solid areas of the at least one solid area and at least one second raster image file containing only one or more halftone areas of the at least one halftone area.
the image file is a raster image file and the control module is configured to perform the step of detecting at least one solid area and at least one halftone area in the raster image file.
the control module is configured to generate based on the image file, a modified image file having at least two bits per pixel, said at least two bits indicating for each pixel whether the pixel is one of the following:
   a non-imaging pixel,
   an imaging pixel to be imaged with the first imaging setting,
   an imaging pixel to be imaged with the second imaging setting,
   optionally an imaging pixel to be imaged with a third imaging setting,
wherein the imaging is done based on the modified image file.

According to another aspect, there is provided a method for imaging a mask layer, comprising the steps: provision of a mask layer, receiving an image file and detecting at least one solid area and at least one halftone area in the image file; imaging an area of the mask layer corresponding to said at least one solid area, using a first imaging setting; imaging an area of the mask layer corresponding to said at least one halftone area, using a second imaging setting which is different from the first imaging setting, wherein prior to or during the imaging a sampling pattern is superimposed on pixels of a halftone area of the at least one halftone area, so that only a portion of the pixels of said halftone area is imaged.

In this manner the at least one solid area may be imaged in a robust and simple manner without using a sampling pattern, whilst a suitable sampling pattern may be used in one or more halftone areas. Preferably, the sampling pattern is then chosen such that Moiré effects are avoided or limited.

In such embodiments, the first and second imaging settings may be such that an imaged spot corresponding to an imaging pixel of the at least one solid area is smaller than an imaged spot corresponding to an imaging pixel of the halftone area.

In such embodiments, for a halftone area of said at least one halftone area having a tonal value below a predetermined value, e.g. in the high-lights, no sampling pattern may be added in said halftone area, and for a halftone area having a tonal value above the predetermined value, a sampling pattern may be added in the halftone area. All halftone areas with a tonal value above the predetermined value may use the same or different sampling patterns.

Preferably, the sampling pattern and said first and second imaging settings are chosen such that, after exposing a relief precursor through the imaged mask layer and developing of the exposed relief precursor, a first surface structure of hills surrounded by valleys is generated on a relief corresponding with said at least one solid area and a second surface structure of hills surrounded by valleys on printing dots corresponding with said at least one halftone area. Such structure will limit any suction effects when the printing plate with ink is pressed against a substrate.

According to a corresponding aspect there is provided a control module configured to receive an image file and to detect at least one solid area and at least one halftone area in the image file. The control module is configured to control an imager so that an area of a mask layer corresponding to said at least one solid area is imaged using a first imaging setting and an area of the mask layer (12) corresponding to a halftone area at least one halftone area is imaged using a second imaging setting which is different from the first imaging setting, wherein prior to or during the imaging a sampling pattern is superimposed on pixels of a halftone area of the at least one halftone area, so that only a portion of the pixels of said halftone area is imaged.

According to another aspect, there is provided a method for imaging a mask layer, comprising the steps: provision of a mask layer, receiving an image file and detecting at least a first and a second halftone area having a different first and second tonal value ranges in the image file; for said first halftone zone, determining a first imaging setting based on a value representative for the first tonal value range; for said second halftone zone, determining a second imaging setting based on a value representative for the second tonal value range; and imaging an area of the mask layer corresponding to said first and second halftone areas, using said determined first and second imaging settings.

In that manner, the surface structure of the relief elements may be adapted in function of the tonal value range. E.g. for larger tonal values the size of the imaged spots may have a larger diameter than for lower tonal values.

Preferably, the first and second tonal value range are ranges above 10%, more preferably above 20%. For example, the first range may be from P1 to P2 and the second range may be all values above P2, wherein P1 is a value between 10% and 30% and P2 a value between 40% and 60%.

Optionally, prior to or during the imaging a sampling pattern may be superimposed on pixels of the first and/or second halftone area, so that only a portion of the pixels of the first and/or second halftone area is imaged. Optionally, whether or not to use a sampling pattern, and/or which sampling pattern to use may also be determined in function of the tonal value of the respective area.

Optionally the method further comprises detecting a solid area in the image file, wherein prior to or during the imaging a sampling pattern is superimposed on pixels of the solid area, so that only a portion of the pixels of the solid area is imaged.

Preferably, the first and second imaging settings are chosen such that, after exposing a relief precursor through the imaged mask layer and developing of the exposed relief precursor, a first surface structure of hills surrounded by valleys is generated on printing dots in said first halftone area and a second surface structure of hills surrounded by valleys on printing dots in said second halftone area.

Preferably, the sampling pattern is any one for sampling patterns disclosed above in connection with other aspects.

Preferably, the first and second imaging settings define any one or more of the parameters disclosed above in connection with other aspects.

Optionally, the step of detecting is done during a raster image processing step.

Alternatively, the image file is a raster image file and the step of detecting in the image file is performed after a raster image processing step. For example, a pattern and size of clusters of imaging pixels may be determined, and based thereon different halftone and solid areas of the image file may be determined.

In an exemplary embodiment a first raster image file is generated containing only the first halftone area and a second raster image file containing only the second halftone area. In such an embodiment, the first and second raster images file may be for example a first one-bit-per-pixel file for the first halftone area and a second one-bit-per-pixel file for the second halftone area. If more than two imaging settings are used, more than two raster image files may be generated. Alternatively, a multi-bit per pixel file may be generated, as has been explained above.

According to a corresponding aspect there is provided a control module configured to receive an image file and to detect at least a first and a second halftone area having a different first and second tonal value ranges in the image file; and to determine, for said first halftone zone, a first imaging setting based on a value representative for the first tonal value range, and for said second halftone zone, a second imaging setting based on a value representative for the second tonal value range; and to control the imaging an area of a mask layer corresponding to said first and second halftone areas, using said determined first and second imaging settings.

A further aspect of the present disclosure concerns a method for imaging a mask layer comprising the steps of generating an image file with at least two bits per pixel, and imaging said mask layer with said image file so that each pixel is imaged in accordance with the associated at least two bits in the image file. Said at least two bits indicate one of the following:
non-imaging pixel,
imaging pixel to be imaged with a first imaging setting,
imaging pixel to be imaged with a second imaging setting, wherein said first and second imaging settings are different,
optionally imaging pixel to be imaged with a third imaging setting,
wherein said third imaging setting is different from said first and second imaging settings.

By generating such a modified imaging file, the imager can be instructed in a convenient manner, whilst allowing to vary the imaging settings. In this way the imaging settings can be changed during the imaging in a convenient manner.

This further aspect of the disclosure may comprise any one of, or any technically possible combinations of the following features:
the first and second imaging settings are such that an imaged spot corresponding to an imaging pixel to be imaged with a first imaging setting is larger than an imaged spot corresponding to an imaging pixel to be imaged with a second imaging setting.
the generating of the image file comprises superimposing a sampling pattern on pixels of at least one first area, preferably at least one solid area, so that only a portion of the pixels of the at least one first area are imaging pixels,
the generating of the pixels is based on data in a received image file, and is preferably based on a tonal value of the pixels in the received image file.
the first and second imaging settings each specifies a value which is representative for a size and/or shape of an imaged spot corresponding with an imaging pixel; wherein preferably the first and second imaging settings define any one or more of the parameters specified above for the first aspect.
the first and second imaging settings are chosen such that, after exposing a relief precursor through the imaged mask layer and developing an exposed relief precursor, a first surface structure of hills surrounded by valleys is generated in at least a first area and a second surface structure of hills surrounded by valleys in at least a second area.

A further aspect of the present disclosure concerns a control module for controlling an imager for imaging a mask layer. The control module is configured to generate an image file with at least two bits per pixel, and to control the imaging of the mask layer with said image file so that each pixel is imaged in accordance with the associated at least two bits in the image file. The at least two bits indicate one of the following:
a non-imaging pixel,
an imaging pixel to be imaged with a first imaging setting,
an imaging pixel to be imaged with a second imaging setting, wherein said first and second imaging settings are different,
optionally, an imaging pixel to be imaged with a third imaging setting, wherein said third imaging setting is different from said first and second imaging settings.
   The value of the two bits may be determined by the control module based on information included in an original image file, e.g. based on whether the pixel is located on a solid area or in a halftone area and/or based on a tonal value of the pixel and/or based on other image information.

In preferred embodiments according to any one of the aspects disclosed above, the first imaging setting is such that, where the first image settings are used, an imaged spot corresponding to a imaging pixel does not overlap with an adjacent imaged spot corresponding to an adjacent imaging pixel; and/or the second imaging setting is such that, where the second image settings are used, an imaged spot corresponding to a imaging pixel does not overlap with an adjacent imaged spot corresponding to an adjacent imaging pixel. In that manner it is avoided that isolated “wells” are created which may cause a sucking of the ink towards the printing plate.

A further aspect of the present disclosure relates to a method for treating a relief precursor, comprising the steps of: the provision of a relief precursor comprising a substrate layer, a photosensitive layer, and a mask layer; imaging the mask layer by a method as disclosed above in relation to the any one of the aspects of the present disclosure; exposing the relief precursor with electromagnetic radiation, preferably UV radiation, so that a portion of the photosensitive layer is cured, and developing the exposed relief precursor by removing a portion of the photosensitive layer that was not exposed.

Preferably the imaging is such that, after the exposing and developing, printing reliefs with a surface structure of hills surrounded by valleys are generated.

A further aspect of the present disclosure also relates to an imaging system, the imaging system being configured to perform any one of the embodiments of the method as disclosed above.

The present disclosure also concerns a control module configured to carry out any one of the embodiments of the method of the present disclosure.

Another aspect of the present disclosure also relates to a system for imaging and optionally further processing a relief precursor, comprising
a control module according to any one of the embodiments disclosed above;
an imager configured to image a mask layer; e.g. an imager comprising means to generate and control at least one beam of electromagnetic radiation. The imager may be a flatbed device or an inner or outer drum device, the latter may be equipped with a rotating drum.

The control module is configured to control the imager according to any one of the embodiments disclosed above.

Preferably, the system further comprises any one or more of the following: at least one transport system configured to transport the relief precursor, a storage system, an exposure means configured to expose the relief precursor through the imaged mask layer, a developing means configured to remove at least a part of non-exposed material from the relief precursor, a drying system, a post-exposure device, a cutting device, a mounting station, a heater. The transport system may comprise one system that connects all the different treatment means or may comprise one or more transport means that connect the different treatment means. The storage system is configured to store the relief precursor and/or the resulting relief plate at any stage of the process, e.g. upstream of the imager, at the end of a mounting station or anywhere in-between.

In exemplary embodiments the imaging of the at least one halftone area and the imaging of the at least one solid area may be done sequentially (in any order) or preferably simultaneously. Preferably, multiple beams are used for the imaging and individual beams thereof can be controlled independently so that imaging can be done simultaneously with different imaging settings. In another embodiment, the multiple beams may comprise a first group of beams and a second group of beams, wherein the first group can be controlled independently of the second group so that imaging can be done simultaneously with the first and second group with different imaging settings

Some embodiments of the present disclosure relate to a computer program comprising computer-executable instructions to control an embodiment of the method as described above in relation to any one of the aspects of the disclosure, when the program is run on a computer.

Some embodiments of the present disclose relate to a digital data storage medium encoding a machine-executable program of instructions to perform any one of the steps of the method as described above in relation to any one of the aspects of the disclosure.

Some embodiments of the present disclose relate to a computer program product comprising computer-executable instructions for controlling or performing the method as described above in relation to any one of the above aspects of the disclosure, when the program is run on a computer.

Any feature of the first aspect of the present disclosure may be combined with any feature of a further aspect of the present disclosure.

### BRIEF DESCRIPTION OF THE DRAWINGS

The above and further aspects of the disclosure will be explained in more detail below on the basis of a number of embodiments, which will be described with reference to the appended drawings. In the drawings:

FIG. 1 illustrates an example embodiment of a method for imaging a relief precursor; FIG. 1 shows on the left-hand side a halftone area, with looking from top left to bottom left: the pixel patterns in the image file for a halftone area, three zones with adjacent imaged spots for forming, after exposing, three relief dots, and a cross section of the relief precursor with the imaged mask layer. Further, in the middle left part the beam used for the imaging the halftone zone (2^{nd} imaging setting) is shown. FIG. 1 also shows on the right-hand side a solid area, with looking from top right to bottom right: a pixel pattern in the image file for a solid area, the pixel pattern with a superimposed sampling pattern, a zone with adjacent imaged spots for forming, after exposing, a single relief, and a cross section of the relief precursor with imaged mask layer. Further, in the middle right part the beam used for imaging the solid zone (1^{st} imaging setting), is shown.

FIG. 2 is a top view of a solid area of an imaged mask layer.

FIG. 3 is a top view of a halftone area of an imaged mask layer.

FIG. 4 is a view similar to FIG. 1, showing a schematic cross section of the relief precursor after a portion of the photosensitive layer is cured and after the uncured portion of the photosensitive layer is removed.

FIG. 5 represents a three-dimensional image of a halftone area illustrating the surface structure on the halftone dots in an exemplary embodiment of a developed relief plate.

FIG. 6 represents a three-dimensional image of a surface structure of solid area in an embodiment on a developed relief plate with a sampling pattern superimposed on the solid area, illustrating the height differences.

FIGS. 7-54 show views of various sampling patterns for use in exemplary embodiments;

FIG. 55 shows one embodiment of the imaging system;

FIGS. 56 and 57 show two methods for imaging and exposing a relief precursor; and

FIGS. 58A, 58B, 58C and 58D show imaged spots for a first tone zone (10%), a second halftone zone (30%), a third halftone zone (70%) and a solid zone (100%).

### DESCRIPTION OF THE INVENTION

Flexographic printing or letterpress printing are techniques which are commonly used for high volume printing. Flexographic or letterpress printing plate are relief plates with printing elements, typically called reliefs or dots, protruding above non-printing elements in order to generate an image on a recording medium such as paper, cardboard, films, foils, laminates, etc. Also, cylindrically shaped printing plates or sleeves may be used.

Various methods exist for making flexographic printing plate precursors. According to conventional methods flexographic printing plate precursors are made from multilayer substrates comprising a backing layer and one or more photocurable layers (also called photosensitive layers). Those photocurable layers are imaged by exposure to electromagnetic radiation through a mask layer containing the image information or by direct and selective exposure to light e.g. by scanning of the plate to transfer the image information in order to obtain a relief plate.

In flexographic printing, ink is transferred from a flexographic plate to a print medium. More in particular, the ink is transferred on the relief parts of the plate, i.e. in the halftone dots or solid reliefs, and not on the non-relief parts. During printing, the ink on the relief parts is transferred to the print medium. Greyscale images are typically created using half-toning using a screening pattern, preferably an AM screening pattern. By greyscale is meant, for a plate printing in a particular colour, the amount of that colour being reproduced. For example, a printing plate may comprise different half-tone dot regions to print with different densities in those regions. In order to increase the amount of ink transferred and to increase the so-called ink density on the substrate, an additional very fine structure is applied to the surface of the printing dots, i.e. the relief areas. This fine surface structure is typically obtained by adding a fine high resolution sampling pattern to the image file, so that it is then transferred to the corresponding mask used for exposure.

Images reproduced by flexographic plates typically include both solid image areas and a variety of grey tone areas, also called halftone areas. A solid area corresponds with a single relief in the printing plate which is completely covered by ink so as to produce the highest density on a print material. A grey tone or halftone area corresponds with an area with multiple printing dots at a distance of each other, i.e. an area where the appearance of the printed image is of a density intermediate between pure white (total absence of ink) and pure colour (completely covered by ink). Grey areas are produced by the process of half-toning, wherein a plurality of relief elements per unit area is used to produce the illusion of different density printing. These relief elements are commonly referred to in the printing industry as ‘halftone dots’. Image presentation is achieved by changing a percentage of area coverage (dot intensity) from region to region. Dot intensity may be altered by altering the dot size (AM screening) and/or the dot density, i.e. the dot frequency (FM screening).

In a flexographic plate, the halftone dots are relief areas having their surface at the top surface of the plate. The plate in the area surrounding the dot has been etched to a depth which reaches to a floor. The height of a halftone dot is the distance of the surface of the dot (and of the plate surface) to the floor. The halftone relief is the relief extending from the floor to the top surface.

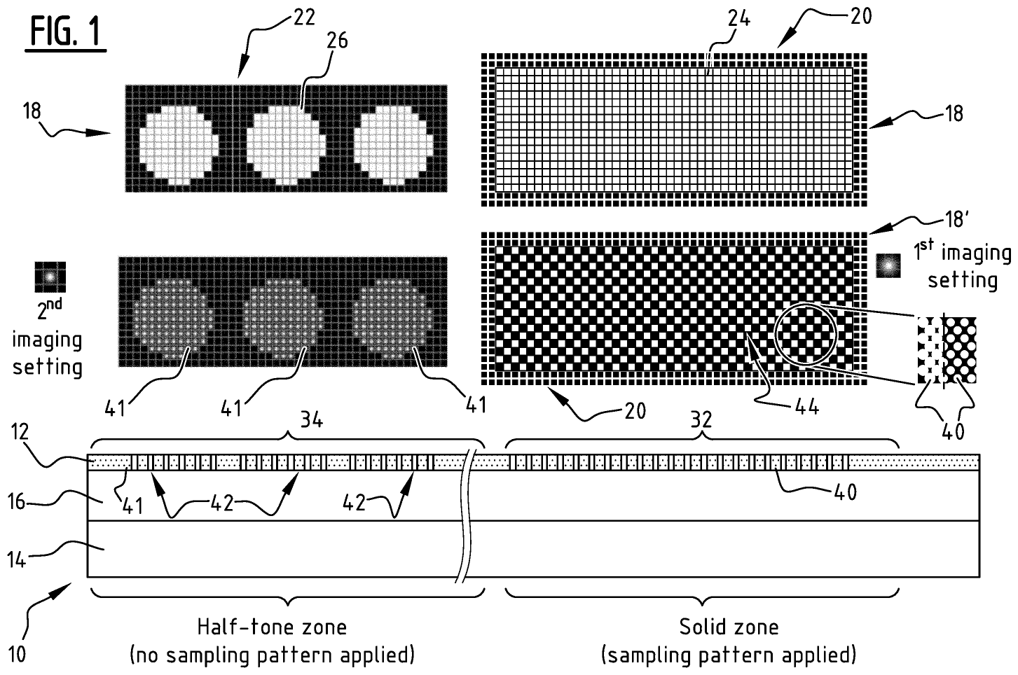

FIG. 1 schematically illustrates an embodiment of a method for imaging a relief precursor 10. The lower part of FIG. 1 shows the cross section of a relief precursor 10 according to one embodiment. The relief precursor 10 comprises a mask layer 12, a substrate layer 14, and a photosensitive layer 16 placed between the mask layer 12 and the substrate layer 14. The relief precursor 10 is an imaged relief precursor before its exposure to electromagnetic radiation which cures a portion of the photosensitive layer 16. The relief precursor is for example a digital relief precursor or an analogue relief precursor. In case of a digital relief precursor the mask layer is an integral layer of the precursor, and the imaging of the mask layer results in an ablated layer, whereas in case of an analogue relief precursor the mask layer is typically a separate layer, such as a film, which comprises areas which are transparent for radiation and areas which are not transparent for radiation, and which is mounted onto the relief precursor prior to exposure with electromagnetic radiation. For example, a non-transparent ablatable layer on a substrate layer may be used and the structures may be generated by ablation, or the transmission of a layer of a film may be changed by exposure with a laser.

For imaging the mask layer 12, first an image file 18 is received. The image file 18 for example represents two-dimensional image data, as shown in the top part of FIG. 1: the left-hand side shows a halftone area 22 of the image file 18 and the right-hand side shows a solid area 20. Prior to or during the imaging, a sampling pattern 44, here a checkerboard pattern, is superimposed on pixels 24 of the at least one solid area 20, so that only a portion of the pixels 24 of the at least one solid area is imaged, as shown in the right middle part of FIG. 1. The two-dimensional image data is to be transferred at least partially to the mask layer 12.

Once the image file 18 is received, the method detects at least one image file solid area 20 and at least one image file halftone area 22 in the image file 18. The image file solid area 20 contains a cluster of at least one solid area imaging pixel 24. The image file halftone area 22 comprises a plurality of imaging pixel clusters (here three imaging pixel clusters are shown) each containing at least one halftone area imaging pixel 26. Prior to or during the imaging a sampling pattern 44 is superimposed on pixels of the at least one solid area 20, so that only a portion of the pixels 24 of the at least one solid area 20 is imaged, see the resulting modified image file portion 18′ in FIG. 1.

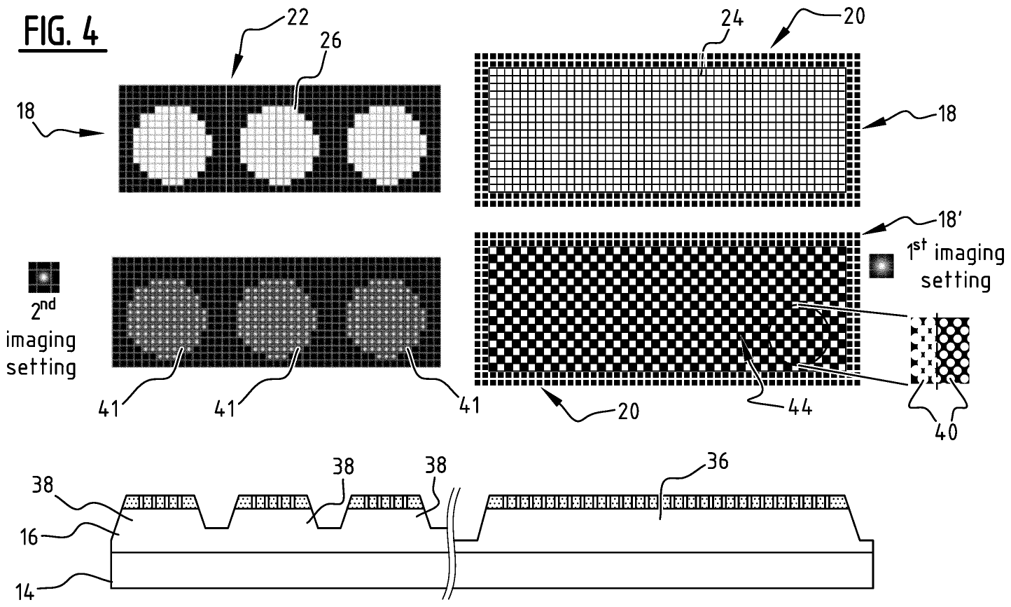

As will explained below, after the mask layer 12 is imaged, it comprises at least one solid zone 32 and at least one halftone zone 34. Each solid zone 32 corresponds to a corresponding solid relief 36 (visible on FIG. 4) of the photosensitive layer 16. Each halftone zone 34 corresponds to a corresponding a plurality of halftone dots 38 (visible on FIG. 4) of the photosensitive layer 16. The solid zone 32 comprises at least one imaged spot 40. As shown in the image on the middle right-hand side of FIG. 1, the imaged spots 40 may not be overlapping or may touch (or may overlap, but this is not shown). The halftone zone 34 comprises a plurality of clusters 42 of imaged spots 41 (here only three clusters 42 are shown for reasons of simplicity), each cluster 42 comprising at least one imaged spot 41, e.g. a more or less circular spot.

A solid area imaging pixel 24 is configured to image a solid zone imaged spot 40 in the solid zone 32. A halftone area imaging pixel 26 is configured to image a halftone zone imaged spot 41 in the halftone zone 34.

It is noted that the imaged spots 40, 41 which are shown schematically in the cross section of FIG. 1 will typically be holes in the mask layer 12.

The original image file 18 may either be a raster image file such as a TIF file or a more high-level image file such as a PDF or PS file. After detection of the at least one solid area 20 and the at least one halftone area 22, the original image file 18 may be converted in a first raster image file containing only the solid areas 20 with the superimposed sampling pattern, and a second raster image file containing only the halftone areas 24. It is noted that the sampling pattern may also be applied during imaging, “on the fly”, in which case it is not included in the first raster image file. The first raster image file is then be used for imaging with the first imaging setting and the second raster image file is then be used for imaging with the second imaging setting. According to another embodiment the original image file 18 is converted in a multi-level image file which for each pixel, indicates an imaging setting to be used.

According to one embodiment the step of detecting at least one image file solid area 20 and/or at least one image file halftone area 22 is done during a raster image processing step.

According to another embodiment the image file 18 is a raster image file. The step of detecting at least one image file solid area 20 and at least one image file halftone area 22 is performed after a raster image processing step.

The solid zone 32 of the mask layer 12 is imaged using a first imaging setting. The halftone zone 34 of the mask layer 12 is imaged using a second imaging setting. The second imaging setting is different from the first imaging setting. FIG. 1 schematically illustrates the first and second imaging settings as a beam with a first and second diameter.

The first and second imaging setting may specify a value representative for the size of the resulting first and second imaged spot 40, 41. The first and second imaging settings may define any one or more of the following parameters:
an intensity value to be used for generating an imaged feature 40, 41 corresponding with an imaging pixel 24, 26, e.g. an intensity value for controlling a beam used for the imaging of the at least one solid zone 32 and the at least one halftone zone 34, respectively;
a time interval to be used for generating an imaged feature 40, 41 corresponding with an imaging pixel 24, 26, e.g. an on-time value for controlling a beam used for the imaging of the at least one solid zone 32 and the at least one halftone zone 34, respectively, i.e. for how long the beam should be turned on for imaging the solid zone 32 and the halftone zone 34; generally the longer the beam is turned on to image one zone 32, 34, the greater the diameter the imaged spot 40, 41 is.
a beam diameter value or beam shape value for controlling a beam used for the imaging of the at least one solid zone 32 and the at least one halftone zone 34, respectively;
a number of passes used for the imaging of the at least one solid zone 32 and the at least one halftone zone 34, respectively;
an indication of an exposure head of a plurality of exposure heads to be used for generating an imaged feature 40, 41 or a group of imaged features 40, 41 corresponding to an imaging pixel 24, 26 or a group of imaging pixels 24, 26 for the imaging of the at least one solid zone 32 and the at least one halftone zone 34, respectively.

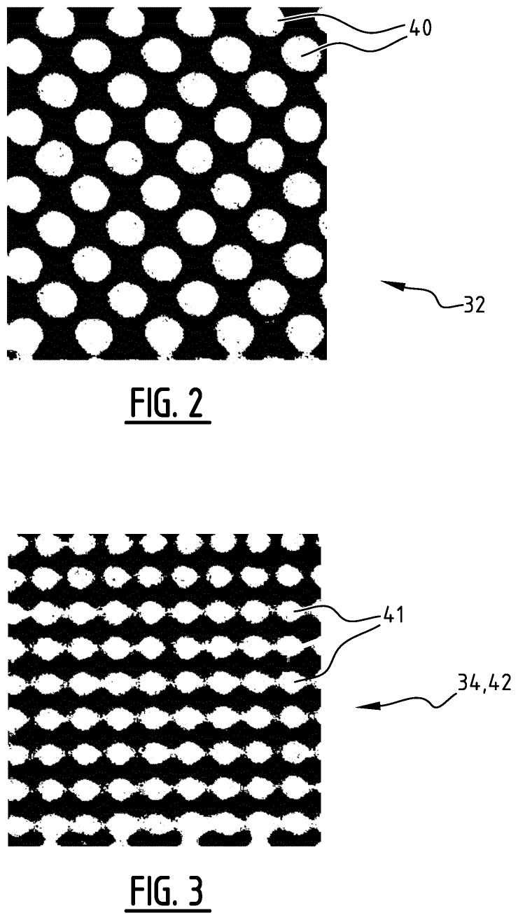

FIG. 2 shows a portion of a solid zone 32 of a mask layer. FIG. 3 shows a portion of a cluster 42 of a halftone zone 34 of a mask layer. In comparison the solid zone 32 has larger solid zone imaged spots 40. The halftone zone 34 has smaller halftone zone imaged spots 41. In an exemplary embodiment, the intensity of the beam used in the solid zone 32 may be at least two times higher than the intensity of the beam used in the halftone zone 34. In an exemplary embodiment, the diameter of the beam used in the solid zone 32 may be at least 10% higher than the diameter of the beam used in the halftone zone 34.

Referring back to FIG. 1, prior to or during the imaging of the mask layer 12, a sampling pattern 44 is superimposed on at least some of the solid area imaging pixels 24, so that only a portion of the solid area imaging pixels 24 is imaged. Put in another way, only a portion of information corresponding to the solid area imaging pixels 24 is transferred to the mask layer 12.

FIG. 4 shows the cross section of a developed relief plate. After exposure to electromagnetic radiation the photosensitive layer 16 comprises at least one solid relief 36 and a plurality of halftone dots 38. According to one embodiment the at least one solid relief 36 corresponds to an area having a tonal value of 100%. According to one embodiment the plurality of halftone dots 38 corresponds to an area having a tonal value of less than 100%. According to some embodiments the distances between the centres of the halftone dots 36 remain the same for all tonal values; only the sizes of the halftone dots 36 change according to different tonal values.

The solid zone 32 of the mask layer of FIG. 1 comprises at least one solid zone imaged spot 40. The solid zone imaged spot 40 corresponds to an imaging pixel of the at least one solid area 20, called solid area imaging pixel 24 above. Each imaged spot 40 generates a hole in the mask layer, and the exposure takes place through these image spots 40, resulting in a surface structure of the solid relief 36 which is schematically shown in FIG. 4 and shown in more detail in FIG. 6.

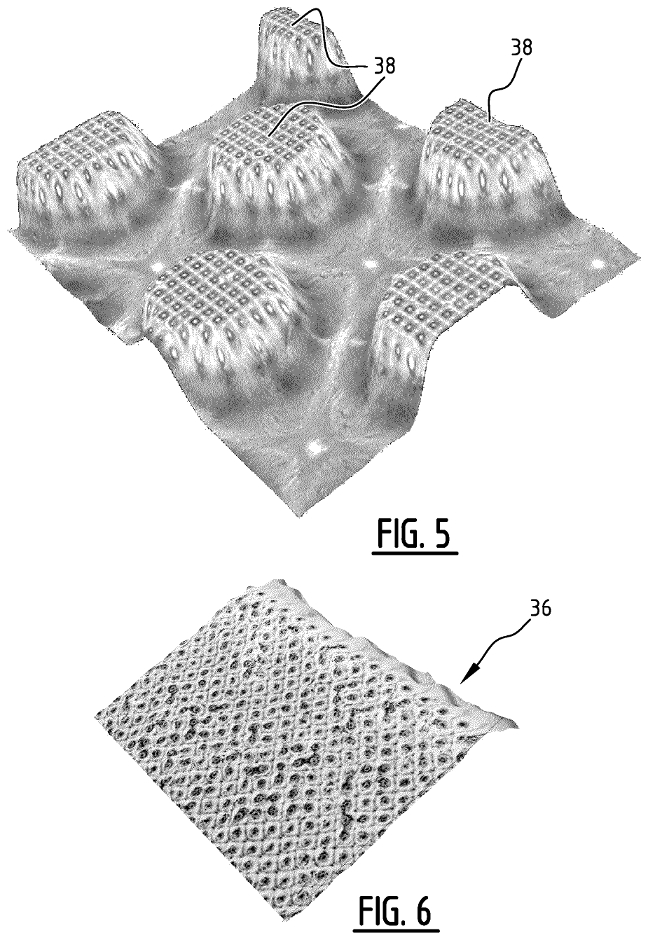

The halftone zone 34 of the mask layer of FIG. 1 comprises clusters 42 with each at least one halftone zone imaged spot 41. The halftone zone imaged spot 41 corresponds to an imaging pixel of the at least one halftone area 22, called halftone area imaging pixel 26 above. Each imaged spot 41 generates a hole in the mask layer, and the exposure takes place through these image spots 41, resulting in a surface structure of the halftone dots 38 which is schematically shown in FIG. 4 and shown in more detail in FIG. 5.

According to one embodiment the solid zone imaged spot 40 is larger than the halftone zone imaged spot 41, as shown in FIGS. 2 and 3. FIGS. 2 and 3 are approximately on the same scale. This can be the result of using a more powerful beam when imaging the solid zone 32 than when imaging the halftone zone 34. Alternatively, this can be the result of using a beam having a greater diameter when imaging the solid zone 32 than when imaging the halftone zone 34. As an illustration of the relative magnitude, the power of the beam used for imaging the solid zone 32 is 2 to 3 times higher than the power of the beam used for imaging the halftone zone 34.

According to a preferred embodiment, no sampling pattern is added in the at least one halftone area 22. This is to say that no sampling pattern is superimposed on the halftone area imaging pixels 26. As a result, all information on the halftone area imaging pixels 26 is imaged without omission and/or additional modifications.

As a variant, a sampling pattern (not shown) is added in the at least one halftone area 22. This is to say that a sampling pattern is superimposed on the halftone area imaging pixels 26. As a result, not all halftone area imaging pixels 26 of a halftone area 22 of the original image file 18 are imaged. The sampling pattern 44 added in the solid area 36 can be the same as or different from the sampling pattern added in a halftone area 22.

As another variant, whether a sampling pattern is added in the at least one halftone area 20 may be made dependent on the tonal value of a halftone area. According to one embodiment, for tonal values below a predetermined value, no sampling pattern is added in the at least one halftone area 22. For tonal values above the predetermined value, a sampling pattern is added in the at least one halftone area 22.

In addition or as an alternative, whether a sampling pattern is added in an area of the image file may be dependent on the size of an isolated cluster of pixels in the image file. For example, for an isolated cluster of pixels with a number of pixels below a predetermined value, no sampling pattern is added. For an isolated cluster of pixels with a number of pixels above the predetermined value, a sampling pattern is added.

According to a preferred embodiment, the sampling pattern 44 and the first and second imaging settings are chosen such that, after exposing a relief precursor through the imaged mask layer 12 and developing an exposed relief plate, a first surface structure of hills surrounded by valleys is generated on the at least one solid relief 36 and a second surface structure of hills surrounded by valleys on the halftone dots 38. Hills here mean the structures protruding further from the floor of the photosensitive layer 16. Valleys here mean the grooves which protrude less far from the floor of the photosensitive layer 16 compared with the hills. Hills surrounded by valleys here means the structures protruding further from the floor alternate with the grooves. FIG. 5 shows the halftone dots 38 with a surface structure comprising hills and valleys. FIG. 6 shows a solid relief 36 with a surface structure comprising hills and valleys.

According to one embodiment, the depth of the valleys of the surface structure on the solid relief 36 is 0.5 μm and 10 μm. According to one embodiment, the depth of the valleys of the surface structure on the halftone dots is between 0.5 μm and 20 μm, preferably between 1 and 10 μm, more preferably between 3 and 10 μm. The total relief depth (i.e. the maximum relief depth in large areas where no imaging pixels are present) is preferably between 100 μm and 4 mm, more preferably between 100 μm and 2 mm, and most preferably between 100 μm and 1 mm. The intermediate relief depth (i.e. the relief depth in an area between halftone dots 38) is preferably between 40 and 60% of the total intermediate depth, e.g. between 30 μm and 2 mm, more preferably between 40 μm and 1 mm.

According to one embodiment, after the relief precursor 10 is exposed and developed, a single printing relief 36 with a first surface structure of hills surrounded by valleys is generated in a solid area 20, and multiple halftone dots 38 with a second surface structure of hills surrounded by valleys is generated in a halftone area 22.

According to one embodiment, prior to the imaging a modified image file is generated. The modified image file has at least two bits per pixel. Said at least two bits indicate for each pixel whether the pixel is one of the following:
a non-imaging pixel (for example represented by the value 00),
an imaging pixel to be imaged with the first imaging setting (for example represented by the value 01),
an imaging pixel to be imaged with the second imaging setting (for example represented by the value 10),
as an optional choice in this embodiment, whether the pixel is an imaging pixel to be imaged with third imaging setting (for example represented by the value 11).

According to this embodiment the imaging of the mask layer 12 is carried out based on the modified image file.

The bits in the image file 18 for example indicate a size, e.g. the diameter of the imaging beam. As an alternative, the bits in the image file 18 indicate an intensity level of the beam. This embodiment especially corresponds to the case when the imaging is carried out by laser beams.

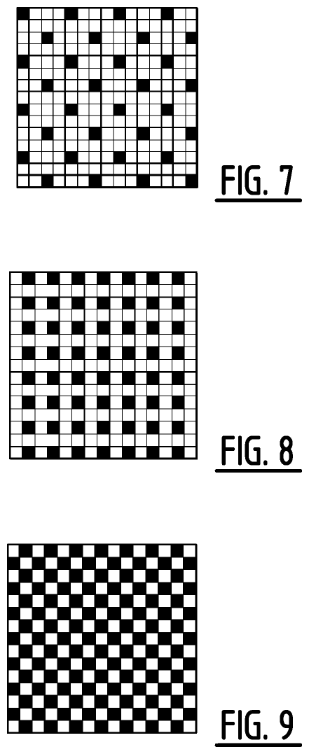

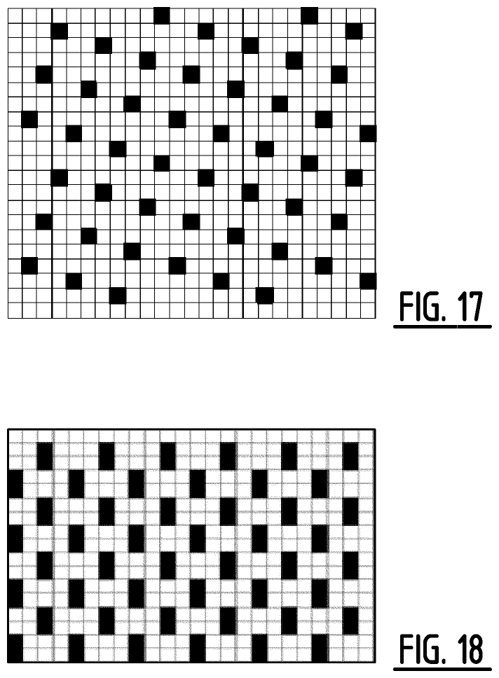

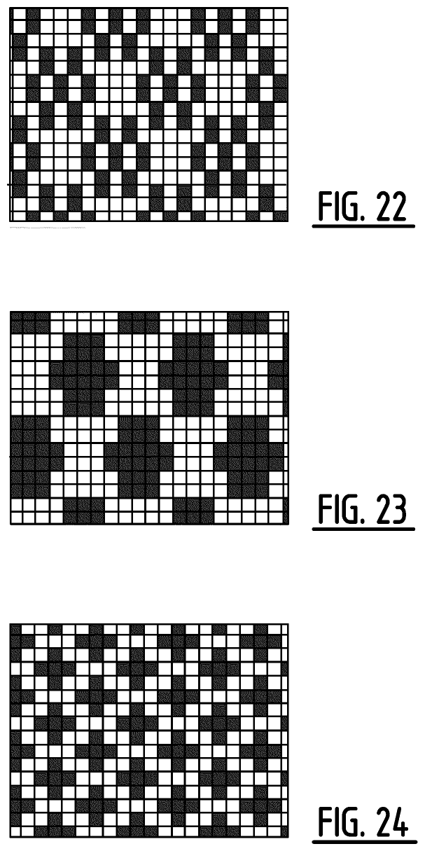

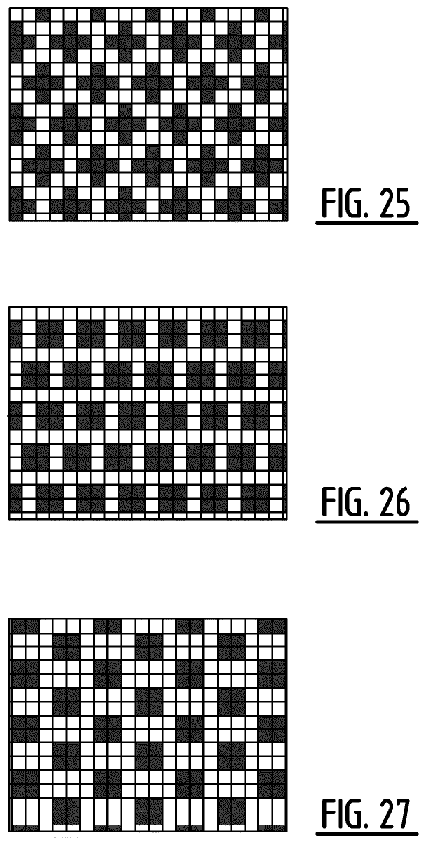

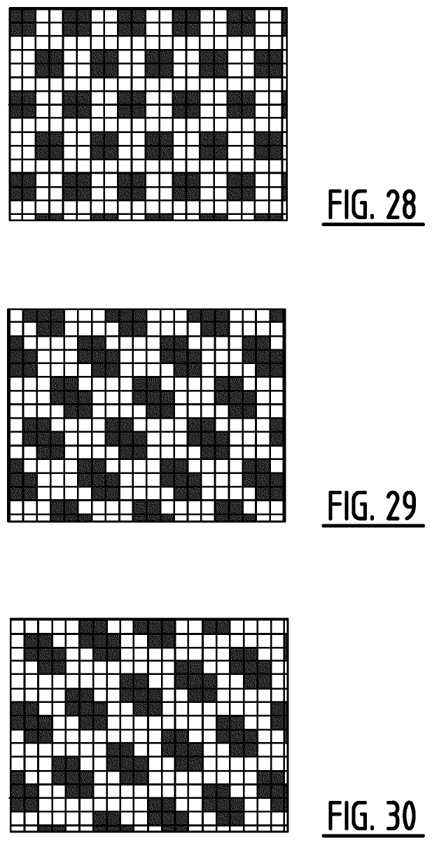

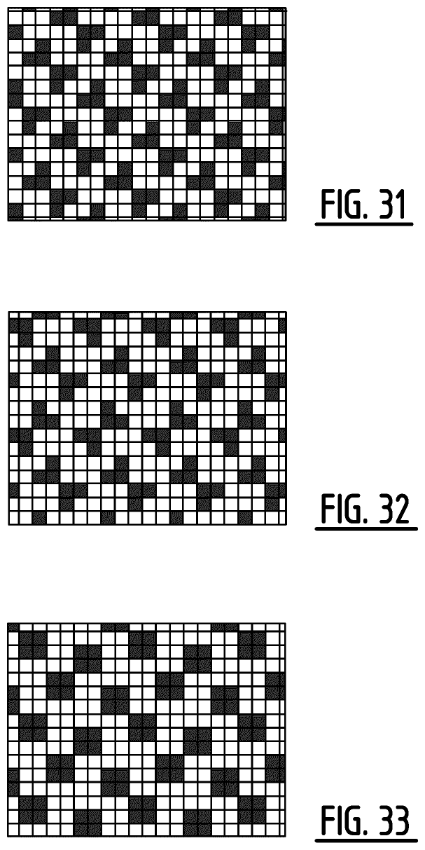

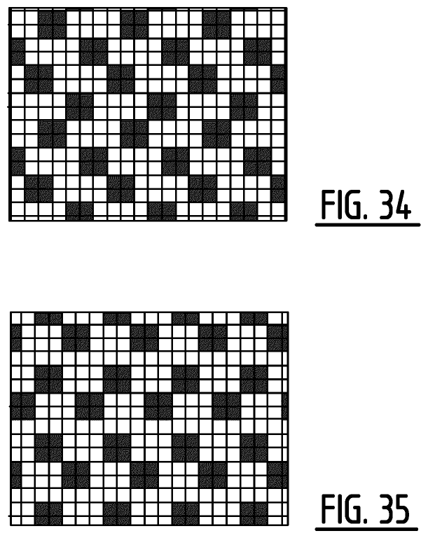

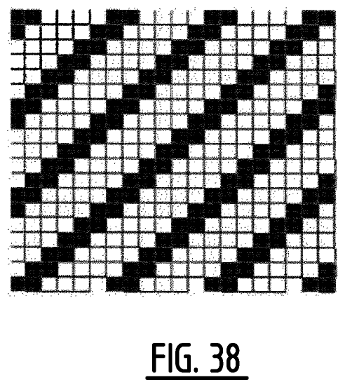

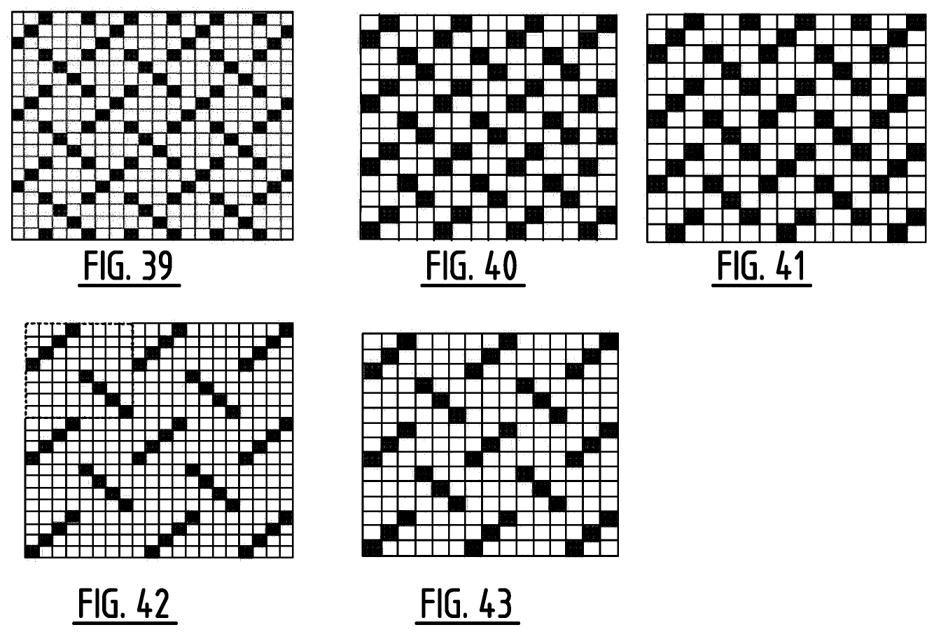

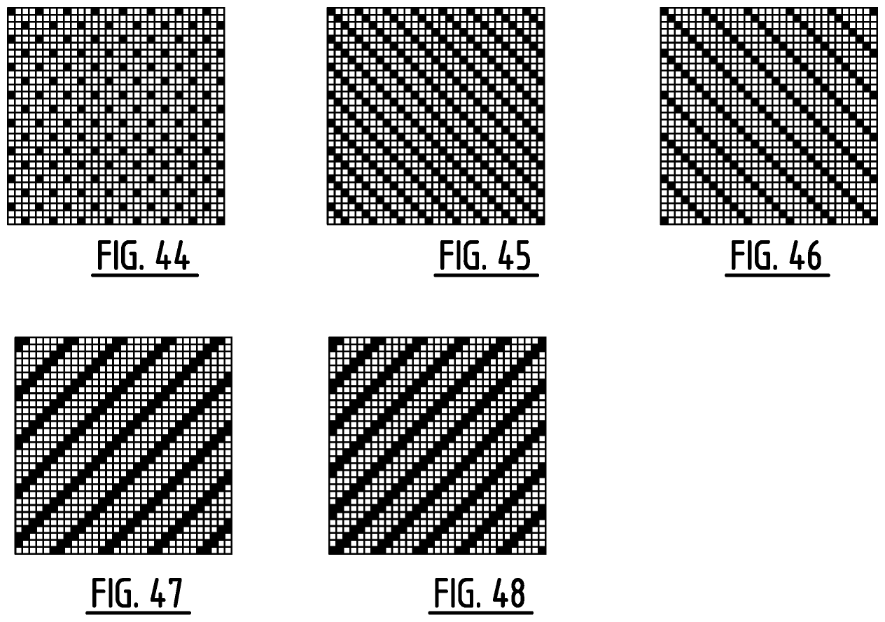

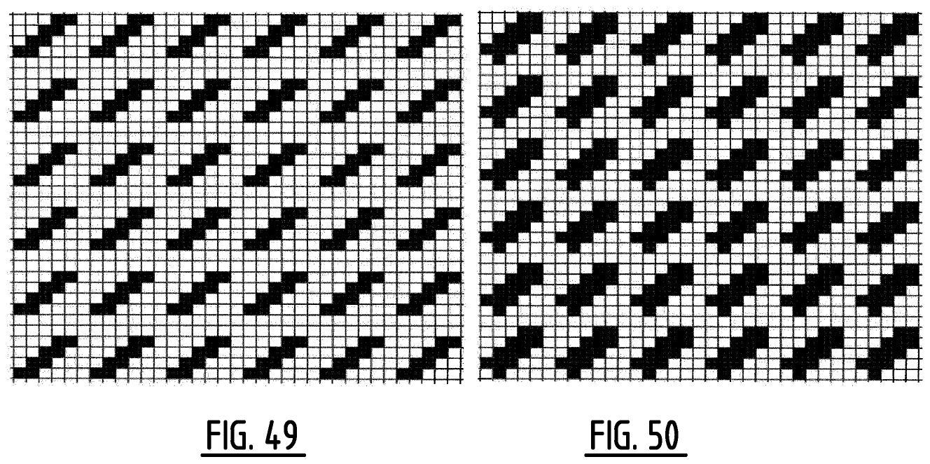

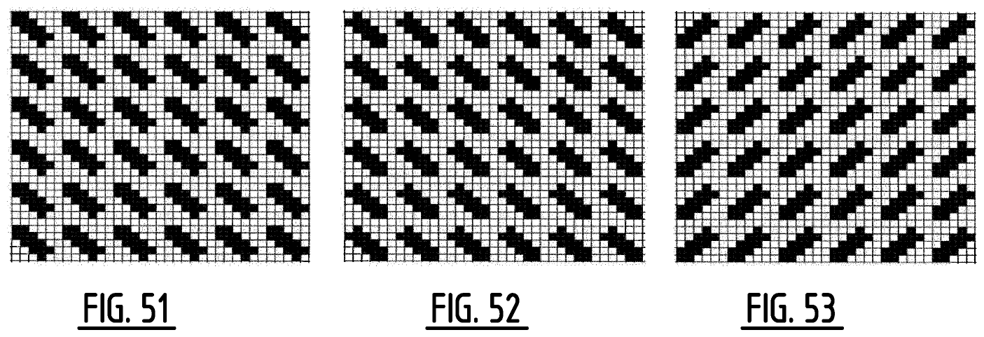

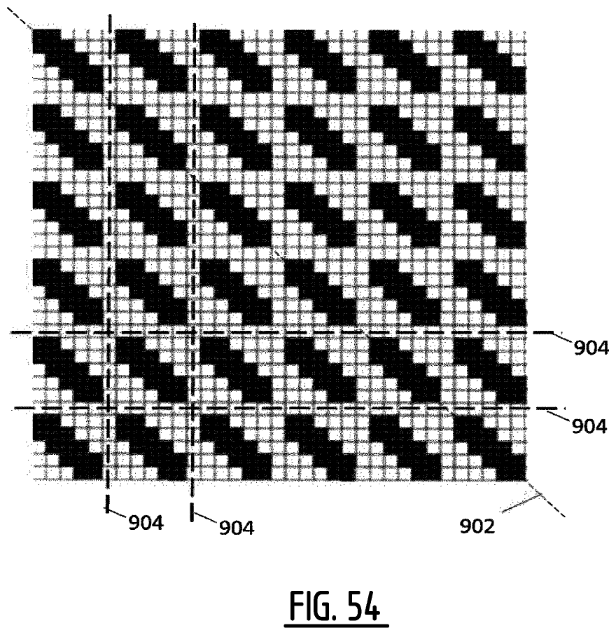

FIGS. 7-54 illustrate various embodiments of possible sampling patterns 44. In these figures, the black portions represent the portions that are ‘sampled’, i.e. the imaging pixels overlapping with the black portions are to be imaged onto the mask layer 12. The white portions represented the portions that are not ‘sampled’, i.e. the imaging pixels overlapping with the white portions will not be imaged onto the mask layer 12.

Amongst FIGS. 7-54, FIGS. 7, 8, 9, 15, 17, 36, 37, 39, 42, 44, 45, and 46 show single pixel patterns, and the other figures show multiple pixel patterns.

According to one embodiment the sampling pattern 44 is a repetition of a block in which one or more imaging pixels are combined with one or more non-imaging pixels.

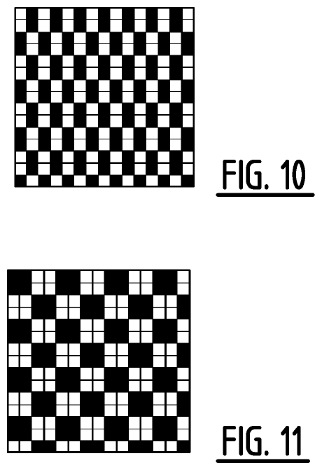

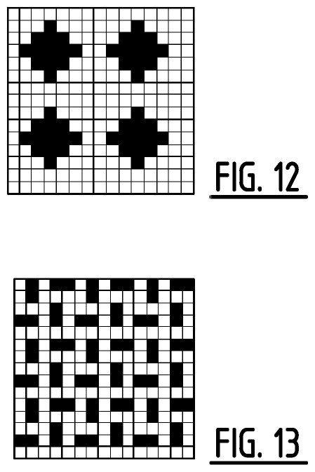

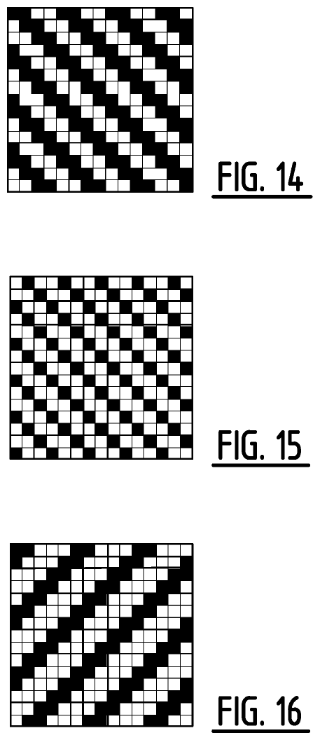

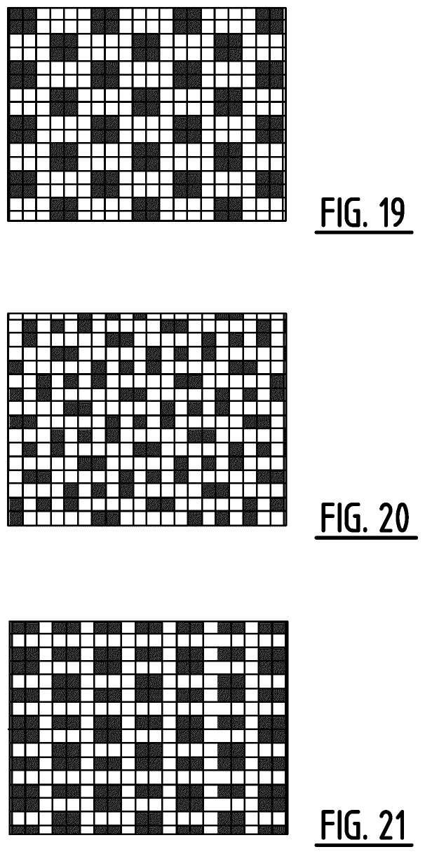

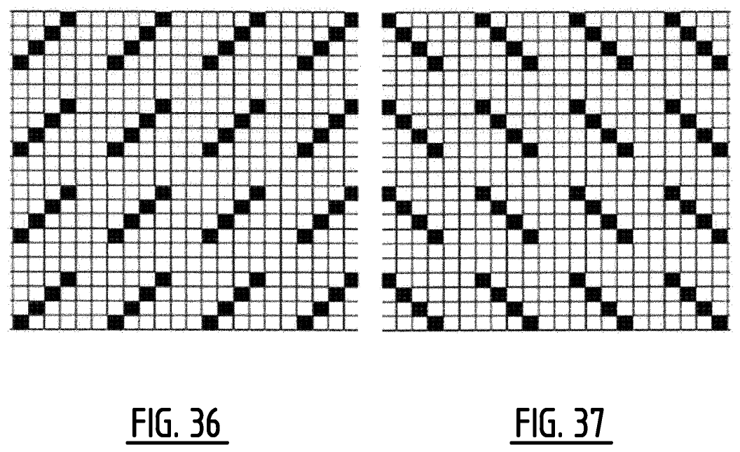

FIGS. 7, 8 and 17 illustrate patterns for which each imaging pixel is surrounded by eight non-imaging pixels. FIG. 9 illustrates a classical checkerboard pattern. FIGS. 10 and 11 illustrate a two-pixel checkerboard pattern and a four-pixel checkerboard pattern, respectively. In the examples of FIGS. 10 and 11 the imaged spots of two adjacent imaging pixels and four adjacent imaging pixels, respectively, will typically overlap. FIG. 12 shows another example of a multiple pixel pattern where a cluster of 13 imaging pixels is repeated. In the example of FIGS. 13 and 18 a cluster of 2 imaging pixels is repeated and in FIG. 13 the clusters are oriented in different directions (some horizontal, some vertical) whilst in FIG. 18 the clusters are all oriented in a vertical direction. In FIG. 18 two imaging pixels are surrounded by 10 non imaging pixels. FIGS. 14-16 and 38 show examples of line patterns. FIG. 19 is another multiple pixel pattern here containing clusters of four pixels each surrounded by 10 non-imaging pixels. FIGS. 20 and 21 show patterns with clusters having a different number of pixels. In FIG. 20 some clusters have 1 pixel and others 2 pixels. In FIG. 21 some clusters have 2 pixel and others 4 pixels. The sampling pattern 44 can also include the dash patterns shown in the FIGS. 36, 37, 39-43, 49-54. The dash patterns are for example lines of imaging pixels which are interrupted.

Generally, the finer patterns, i.e. the patterns with relatively small pixel clusters or the single pixel files are preferred for high quality colour work, such as for printing on labels and some packaging materials. For other materials, such as corrugated cardboard, the multiple pixel patterns are generally preferred. Further, the image setting of an area may be chosen in function of the choice of the sampling pattern. For example, for multiple pixel patterns, the size of the beam may have a larger diameter than for single pixel patterns, or the size may be chosen in function of the multiple pixel pattern used.

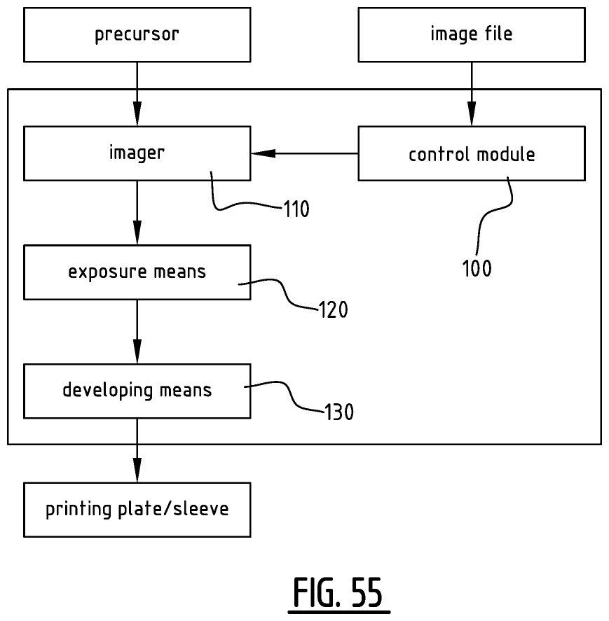

FIG. 55 illustrates a system to convert a relief precursor to a relief printing plate or sleeve. The system comprises a control module 100, an imager 110, an exposure means 120 and a developing means 130. After the mask layer on the precursor is imaged by the imager 110 using the converted image file and/or imaging instructions generated by the control module 100, the precursor is exposed to electromagnetic radiation in the exposure means 120. The electromagnetic radiation changes the properties of the exposed parts of the photosensitive layer 16 such that in the following developing means non-exposed portions of the photosensitive layer are removed by the developing means 130 and a relief printing plate or sleeve is formed. This relief printing plate or sleeve may be treated further and may finally be used as a printing plate.

After the mask layer 12 is imaged in the imager 110, the relief precursor 10 is exposed to electromagnetic radiation in the exposure means 120 so that a portion of the photosensitive layer 16 is cured. The electromagnetic radiation may have a wavelength in the range of 200 to 2000 nm, preferably it is ultraviolet (UV) radiation with a wavelength in the range of 200 to 450 nm.

After a portion of the photosensitive layer 16 is cured, the exposed relief precursor 10 is developed by the developing means 130 by removing a portion of the photosensitive layer 16 that was not exposed to the electromagnetic radiation and that is therefore not cured. A skilled person is familiar with various ways of exposing the relief precursor 10 to electromagnetic radiation, and of developing an exposed relief precursor 10.

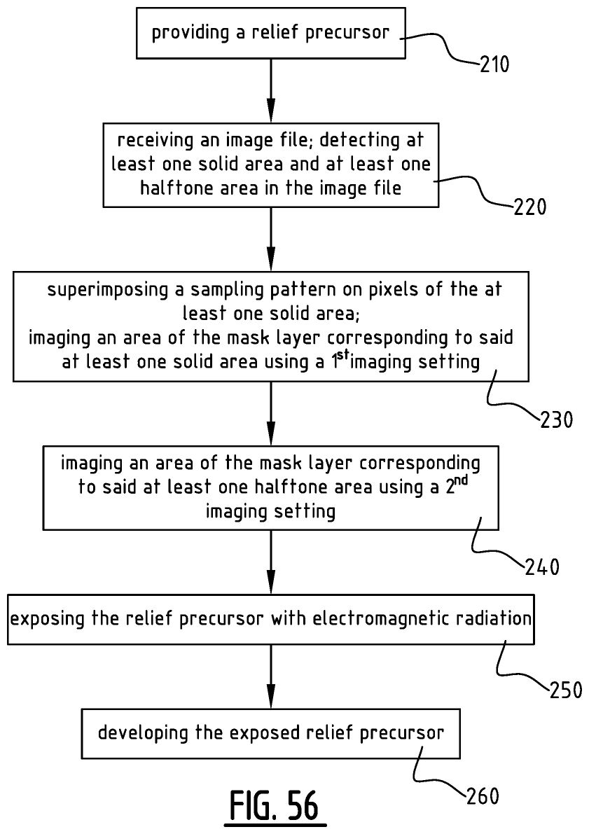

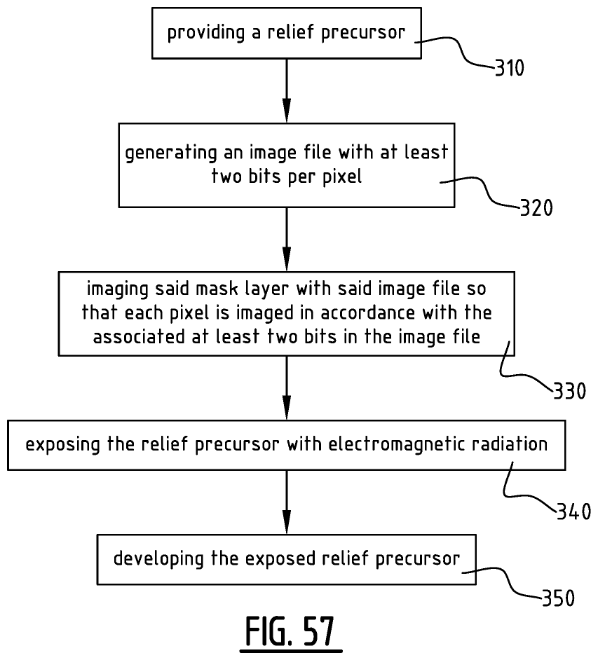

FIGS. 56 and 57 illustrate two embodiments of a method for imaging a relief precursor. In a first step 210, 310 a relief precursor 10 comprising a mask layer 12, a substrate layer 14, and a photosensitive layer 16 is provided. The property of the relief precursor 10, including the property of the mask layer 12, the substrate layer 14, and the photosensitive layer 16 can be identical to that described above. The step of providing the relief precursor 10 can also be identical to that described above.

In a second step 220 an image file 18 is analysed to detect at least one solid are and/or at least one halftone area. Either different raster image files may be generated as explained above or a modified image file with at least two bits per pixel may be generated after the analysis in the manner described above. FIG. 57 shows an embodiment where a two bits per pixel image file is generated in step 330. This file may be generated beforehand or may be based on the detecting of step 220. Each bit amongst the at least two bits indicates one of the following:
a non-imaging pixel (for example represented by the value 00),
an imaging pixel to be imaged with a first imaging setting (for example represented by the value 01),
an imaging pixel to be imaged with a second imaging setting (for example represented by the value 10),
as an optional choice in this embodiment, an imaging pixel to be imaged with a third imaging setting (for example represented by the value 11).

The first and second imaging settings are different. Under the optional choice in this embodiment, the third imaging setting is different from the first and second imaging settings.

Next the mask layer 12 is imaged in step 230, 240; 330 either using with the modified two-bit-per-pixel image file which has been generated, or using multiple raster image files and further instructions regarding the first and second imaging settings. Each imaging pixel is imaged with the corresponding imaging setting to create corresponding imaged spots in the mask layer 12. It is noted that steps 230 and 240 may be done in any order or even simultaneously. Preferably, multiple beams are used for the imaging and individual beams thereof or multiple sets of beams thereof can be controlled independently so that imaging can be done simultaneously with different imaging settings.

According to an exemplary embodiment, the image settings used in steps 230, 240; 330 are such that an imaged spot corresponding to an imaging pixel to be imaged with a first imaging setting is larger than an imaged spot corresponding to an imaging pixel to be imaged with a second imaging setting. This is for example achieved by using a beam with a higher intensity value under the first imaging setting compared with the intensity value of the beam under the second imaging setting. Alternatively, this is achieved by using a beam with a larger diameter under the first imaging setting compared with the diameter of the beam under the second imaging setting.

According to an exemplary embodiment shown in FIG. 56 a sampling pattern is superimposed on pixels of at least one first area, preferably a solid area, so that only a portion of the pixels of the at least one first area are imaging pixels. In addition or as a variant, a sampling pattern is superimposed on pixels of at least one second area, preferably a halftone area, so that only a portion of the pixels of the at least one second area are imaging pixels. The sampling pattern superimposed on the second area can be identical to or different from the sampling pattern superimposed on the first area. Examples of the sampling pattern can be those described in detail above.

After the mask layer 12 is imaged, in step 250, 340 the relief precursor 10 is exposed to electromagnetic radiation so that a portion of the photosensitive layer 16 is cured. The electromagnetic radiation may have a wavelength in the range of 200 to 2000 nm, preferably it is ultraviolet (UV) radiation with a wavelength in the range of 200 to 450 nm.

After a portion of the photosensitive layer 16 is cured, the exposed relief precursor 10 is developed in step 260, 350 by removing a portion of the photosensitive layer 16 that was not exposed to the electromagnetic radiation and that is therefore not cured.

According to one embodiment the first and second imaging settings are chosen such that, after the relief precursor 10 is exposed and developed, a first surface structure of hills surrounded by valleys is generated in at least a first area and a second surface structure of hills surrounded by valleys in at least a second area, for example as illustrated in FIGS. 5 and 6. The first surface structure may be different from the second surface structure.

According to one embodiment the halftone zone 34 of the mask layer 12 comprises a first halftone zone (not represented in the Figures) and a second halftone zone (not represented in the Figures). The first halftone area is imaged using the first imaging setting as explained above. The second halftone area is imaged a using third imaging setting different from the first imaging setting. Preferably the third imaging setting is different from the second imaging setting as well.

According to one embodiment the third imaging setting at least differs from the first imaging setting in that the intensity of the beam (optical power per unit area in W/cm²) used to generate the features in the second halftone zone is different from the intensity of the beam used to generate the features in the first halftone zone and/or in that the diameter of the beam used to generate the features in the second halftone zone is different from the diameter of the beam used to generate the features in the first halftone zone. This will result in the imaged spots in the first halftone zone being smaller i.e. having a lower diameter than those in the second halftone zone.

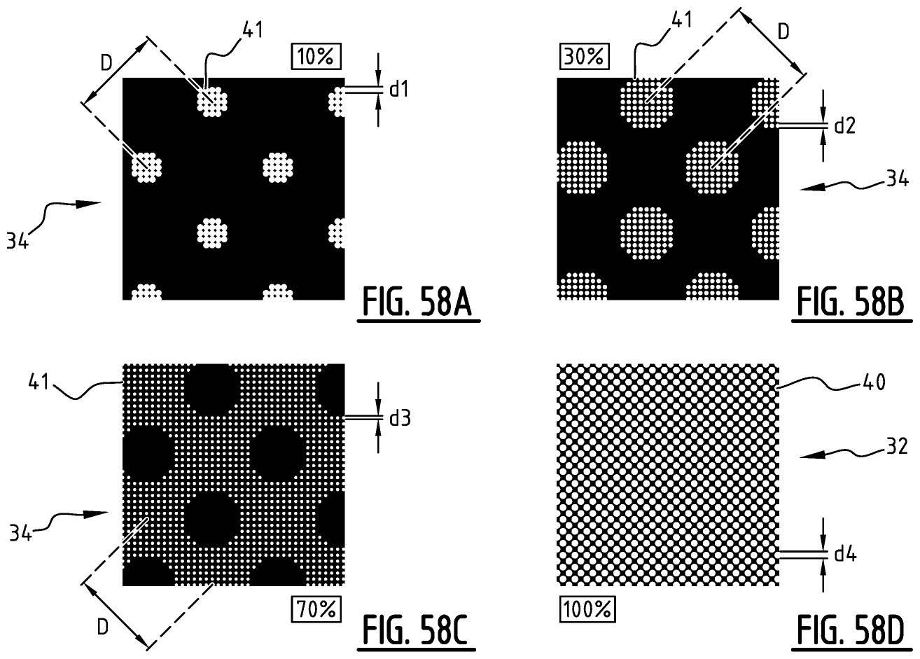

FIGS. 58A-58D illustrate an example where different imaging settings have been used for halftone zones 34 with different tonal values. For example, for small tonal values, e.g. between 0 and 10%, a first diameter d1 may be used so that touching or overlapping imaged spots 41 are obtained, cf. FIG. 58A. For larger tonal values, e.g. between 10 and 50%, a second diameter d2 may be used which is smaller than d1 so that the imaged spots 41 are not overlapping, see FIG. 58B, and for even larger tonal values, e.g. between 50 and 99%, an even smaller diameter d3<d2 may be used, see FIG. 58C. Alternatively, a sampling pattern could be used for those even larger tonal values in combination with a larger diameter. For the solid zone 32 (100%) a sampling pattern may be combined with a diameter d4>d1, see the imaged spots 40 in FIG. 58D.

As illustrated in FIGS. 58A-58D, embodiments of the invention are especially useful for classic amplitude modulated (AM) screens, where the distance D between adjacent dots of a halftone area is the same for halftone areas having different tonal values. The tonal value of the halftone area is then determined by the size of a group of clustered imaging pixels corresponding with clustered imaged spots 41 (i.e. the size of a dot). However, the skilled person understands that other embodiments of the invention may be used for frequency modulated (FM) screens or AM and FM screens, where the distance D is not constant.

According to one embodiment prior to or during the imaging of the first halftone zone of the mask layer 12, a first halftone sampling pattern may be superimposed on the pixels configured for imaging the first halftone zone. According to an embodiment prior to or during the imaging of the second halftone zone of the mask layer 12, a sampling pattern may be superimposed on the pixels configured for imaging the second halftone zone. The sampling pattern superimposed on the pixels for imaging the first halftone zone may be identical to or different from the sampling pattern superimposed on the pixels for imaging the second halftone zone. According to another embodiment the imaging of neither the first halftone zone nor the second halftone zone involves superimposing a sampling pattern.

According to some embodiments the photosensitive layer 16 in the present disclosure is essentially identical to the substrate layer described in WO 2020/188041 A1 in the name of the applicant, which in included herein by reference.

Whilst the principles of the invention have been set out above in connection with specific embodiments, it is to be understood that this description is merely made by way of example and not as a limitation of the scope of protection which is determined by the appended claims.

1. A method for imaging a mask layer, comprising the steps:
providing a mask layer,
receiving an image file and detecting at least one solid area and at least one halftone area in the image file, a halftone area corresponding with an area with multiple printing dots at a distance of each other;
imaging an area of the mask layer corresponding to said at least one solid area, using a first imaging setting, wherein prior to or during the imaging a sampling pattern is superimposed on pixels of the at least one solid area, so that only a portion of the pixels of the at least one solid area is imaged; and
imaging an area of the mask layer corresponding to said at least one halftone area, using a second imaging setting which is different from the first imaging setting, wherein the first and second imaging settings each specify a value which is representative for a size and/or shape of an imaged spot corresponding with an imaging pixel.

2. The method of claim 1, wherein the first and second imaging settings are such that an imaged spot corresponding to an imaging pixel of the at least one solid area is larger than an imaged spot corresponding to an imaging pixel of the at least one halftone area.

3. The method of claim 1, wherein no sampling pattern is added in the at least one halftone area.

4. The method of claim 1, wherein, for a halftone area of said at least one halftone area having a tonal value below a predetermined value, no sampling pattern is added in said halftone area, and for a halftone area having a tonal value above the predetermined value, a sampling pattern is added in the halftone area.

5. A method for imaging a mask layer, comprising the steps:
provision of a mask layer,
receiving an image file and detecting at least one solid area and at least one halftone area in the image file, a halftone area corresponding with an area with multiple printing dots at a distance of each other;
imaging an area of the mask layer corresponding to said at least one solid area, using a first imaging setting; and
imaging an area of the mask layer corresponding to said at least one halftone area, using a second imaging setting which is different from the first imaging setting, wherein the first and second imaging settings each specify a value which is representative for a size and/or shape of an imaged spot corresponding with an imaging pixel, wherein prior to or during the imaging a sampling pattern is superimposed on pixels of a halftone area of the at least one halftone area, so that only a portion of the pixels of said halftone area is imaged.

6. The method of claim 5, wherein the first and second imaging settings are such that an imaged spot corresponding to an imaging pixel of the at least one solid area is smaller than an imaged spot corresponding to an imaging pixel of the halftone area.

7. The method of claim 5, wherein for a halftone area of said at least one halftone area having a tonal value below a predetermined value, no sampling pattern is added in said halftone area, and for a halftone area having a tonal value above the predetermined value, a sampling pattern is added in the halftone area.

8. The method of claim 1, wherein said sampling pattern and said first and second imaging settings are chosen such that, after exposing a relief precursor through the imaged mask layer and developing of the exposed relief precursor, a first surface structure of hills surrounded by valleys is generated on a solid relief corresponding with said at least one solid area and a second surface structure of hills surrounded by valleys on a plurality of halftone dots corresponding with said at least one halftone area.

9. A method for imaging a mask layer, comprising the steps:
providing a mask layer,
receiving an image file and detecting at least a first and a second halftone area having a different first and second tonal value range in the image file, a halftone area corresponding with an area with multiple printing dots at a distance of each other;
for said first halftone zone, determining a first imaging setting based on a value representative for the first tonal value range;
for said second halftone zone, determining a second imaging setting based on a value representative for the second tonal value range, wherein the first and second imaging settings each specify a value which is representative for a size and/or shape of an imaged spot corresponding with an imaging pixel; and
imaging an area of the mask layer corresponding to said first and second halftone areas, using said determined first and second imaging settings.

10. The method of claim 9, wherein said first and second tonal value range are above 10%, preferably above 20%.

11. The method of claim 9, wherein prior to or during the imaging a sampling pattern is superimposed on pixels of the first and/or second halftone area, so that only a portion of the pixels of the first and/or second halftone area is imaged.

12. The method of claim 9, further comprising detecting a solid area in the image file, wherein prior to or during the imaging a sampling pattern is superimposed on pixels of the solid area, so that only a portion of the pixels of the solid area is imaged.

13. (canceled)

14. The method of claim 1, wherein the sampling pattern is a repetition of a block in which one or more imaging pixels are combined with one or more non imaging pixels.

15. (canceled)

16. The method of claim 1, wherein the image file represents two-dimensional image data, wherein preferably the image file is a 1 bit per pixel file or a multi-level image file with multiple bits per pixel.

17. The method claim 1, wherein the first and second imaging settings define any one or more of the following parameters:
an intensity value to be used for generating an imaged feature corresponding with an imaging pixel, e.g. an intensity value for controlling a beam used for the imaging of the at least one solid area and the at least one halftone area, respectively,
a time interval to be used for generating an imaged feature corresponding with an imaging pixel, e.g. an on-time value for controlling a beam used for the imaging of the at least one solid area and the at least one halftone area, respectively,
a beam diameter value or beam shape value for controlling a beam used for the imaging of the at least one solid area and the at least one halftone area, respectively,
a number of passes used for the imaging of the at least one solid area and the at least one halftone area, respectively, and
an indication of an exposure head of a plurality of exposure heads to be used for generating an imaged feature or a group of imaged features corresponding to a pixel or a group of pixels for the imaging of the at least one solid area and the at least one halftone area, respectively.

18. The method of claim 1, wherein a solid area of the at least one solid area corresponds to an isolated cluster of imaging pixels resulting in a single relief and wherein a halftone area of the at least one halftone area corresponds to multiple similarly sized imaging pixel clusters at a distance of each other resulting in multiple similarly sized relief dots.

19. The method of claim 1, wherein the step of detecting is done during a raster image processing step, and wherein optionally a first raster image file is generated containing only one or more solid areas of the at least one solid area and a second raster image file containing only one or more halftone areas of the at least one halftone area; and/or wherein the image file is a raster image file and the step of detecting in the image file is performed after a raster image processing step.

20. (canceled)

21. The method of claim 1, wherein prior to the imaging, a modified image file is generated, said modified image file having at least two bits per pixel, said at least two bits indicating for each pixel whether the pixel is one of the following:
a non-imaging pixel,
an imaging pixel to be imaged with the first imaging setting,
an imaging pixel to be imaged with the second imaging setting, and
optionally an imaging pixel to be imaged with a third imaging setting,
wherein the imaging is done based on the modified image file.

22. A method for imaging a mask layer comprising the steps:
generating an image file with two bits per pixel, said two bits indicating one of the following:
non-imaging pixel,
imaging pixel to be imaged with a first imaging setting,
imaging pixel to be imaged with a second imaging setting, wherein said first and second imaging settings are different,
optionally imaging pixel to be imaged with a third imaging setting,
wherein said third imaging setting is different from said first and second imaging settings;
imaging said mask layer with said image file so that each pixel is imaged in accordance with the associated the two bits in the image file.

23. The method of claim 22, wherein the first and second imaging settings are such that an imaged spot corresponding to an imaging pixel to be imaged with a first imaging setting is larger than an imaged spot corresponding to an imaging pixel to be imaged with a second imaging setting.

24. The method of claim 22, wherein the generating of the image file comprises superimposing a sampling pattern on pixels of at least one first area, preferably at least one solid area, so that only a portion of the pixels of the at least one first area are imaging pixels; and/or wherein the generating of the pixels is based on data in a received image file, and is preferably based on a tonal value of the pixels in the received image file.

25-27. (canceled)

28. The method of claim 1, wherein the first imaging setting is such that, where the first image settings are used, an imaged spot corresponding to a imaging pixel does not overlap with an adjacent imaged spot corresponding to an adjacent imaging pixel; and/or wherein the second imaging setting is such that, where the second image settings are used, an imaged spot corresponding to a imaging pixel does not overlap with an adjacent imaged spot corresponding to an adjacent imaging pixel.

29-30. (canceled)

31. A computer program product comprising computer-executable instructions to control the method of claim 1 when the program is run on a computer.

32-38. (canceled)
